(19) United States
(12) Patent Application Publication
(10) Pub. No.: US 2005/0082515 A1
(43) Pub. Date: Apr. 21, 2005

(54) Coating composition and method of manufacturing organic EL element

(75) Inventors: Mikio Masuichi, Kyoto (JP); Tsuyoshi Matsuka, Kyoto (JP); Yukihiro Takamura, Kyoto (JP); Masafumi Kawagoe, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 10/927,988

(22) Filed: Aug. 26, 2004

(30) Foreign Application Priority Data
Oct. 17, 2003 (JP) 2003-358260

(51) Int. Cl. G03G 15/00

(52) U.S. Cl. 252/500

(57) ABSTRACT

Using a mixture of (BAYTRON P) of PEDT (polyethylene dioxythiophene) and PSS (polystyrene sulfonic acid) as a hole transportation material and using water and ethanol as polar solvents, a coating composition having a contact angle of 35 degrees or smaller with respect to an ITO layer is obtained. The coating composition is then poured for coating upon exposed surfaces of first electrodes (ITO) 4R, 4G and 4B enclosed by barrier walls 6. Thus applied coating composition uniformly spreads all over the first electrodes 4R, 4G and 4B. As the coating composition naturally dries at a room temperature for about fifteen seconds, the solvents are removed from the coating composition.

### CROSS REFERENCE TO RELATED APPLICATION

The disclosure of Japanese Patent Applications No.2003-358260 filed Oct. 17, 2003 including specification, drawings and claims is incorporated herein by reference in its entirety.

### BACKGROUND OF THE INVENTION

1. Field of the Invention

The present invention relates to a coating composition for forming a hole transporting layer, a hole injecting layer and the like, and a method of manufacturing an organic EL element using such a coating composition.

2. Description of the Related Art

An organic EL (electroluminescence) element which uses an organic EL material as a luminous layer has been recently researched and developed as a thin display apparatus. These research efforts on organic EL elements have identified that the luminous efficiency, the durability of an organic EL element could be increased with a hole injecting layer or a hole transporting layer (hereinafter referred to as a “hole transporting layer”) disposed between the anode and a luminous layer. Noting this, various types of manufacturing methods have been proposed for the purpose of forming a hole transporting layer on the anode before forming a luminous layer. According to one of them, a hole transporting layer is formed by an ink jet method as described in Japanese Patent Application Laid-Open Gazette No. 2000-323276 (hereinafter referred to as “Patent Literature 1”).

This conventional method is a method according to which an ink composition obtained by dissolving or dispersing a hole transportation material in a solvent is injected from an ink jet head and applied upon the anode (transparent electrode) to thereby form a hole transporting layer. To be more specific, the hole transporting layer is formed on the anode in the following manner. The ink composition for hole transporting layer is injected at the head of an ink jet printing apparatus (which may be EPSON MJ-930C for instance) and applied upon the anode for patterning. The solvent is removed in vacuum (1 Torr) at a room temperature for twenty minutes and subjected to heat processing (post baking) in atmosphere at 200° C. for ten minutes, thereby forming the hole transporting layer. An ink jet method thus realizes the effects that (1) it is possible to form very fine patterns in a simple manner in a short period of time and (2) it is possible to efficiently use the hole transportation material since only a necessary amount of the material needs be applied in necessary areas.

### SUMMARY OF THE INVENTION

However, formation of a hole transporting layer by an ink jet method necessitates solvent removing processing and heat processing over a long period of time after coating with an ink composition for patterning. This gives rise to a problem that a tact time required to form the hole transporting layer becomes long. An approach for shortening of the tact time may be to assign a plurality of units for solvent removing processing and heat processing after coating for patterning, namely, so-called bake units for one coating unit which applies a hole transportation material upon the anode, for example. However, this causes a problem that a manufacturing apparatus (=coating unit+bake units) for forming the hole transporting layer becomes large and a cost of the apparatus increases. Because of this, there is a need for a coating composition and an organic EL element with which it is possible to form a hole transporting layer in a short period.

A primary object of the present invention is to provide a coating composition coats a predetermined base material favorably, dries up in a short period of time after coating and forms a hole transporting layer, and to provide a method of efficiently manufacturing an organic EL element using such a coating composition.

The present invention is directed to a coating composition and a method of manufacturing an organic EL element such a coating composition. The coating composition which is to be applied upon a surface of a predetermined base material and which contains a hole transportation material, wherein the contact angle of the coating composition with respect to the surface of the base material is 35 degrees or smaller. A method of manufacturing organic EL element comprises an electrode forming step of forming an electrode having a predetermined pattern on a substrate, a barrier wall (bank) forming step of forming barrier walls on the substrate such that the barrier walls will correspond to the pattern, and a coating step of coating exposed surfaces of the electrode which are enclosed by the barrier walls by means of pouring a coating composition thereon, and wherein the coating composition contains a hole transportation material and has a contact angle of 35 degrees or smaller with respect to the surface of the electrode.

With such a structure, when poured upon the exposed surfaces of the electrode enclosed by the barrier walls, the coating composition has a relatively small contact angle (35 degrees or less) with respect to the surface of the base material (electrode) and spreads uniformly over the exposed surfaces of the electrode. A solvent is then removed out over a short time from the coating composition thus applied in the manner above.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIGS. 1A through 1E are drawings which show an embodiment of a method of manufacturing organic EL element according to the present invention;

FIGS. 2A through 2D are drawings which show the embodiment of a method of manufacturing organic EL element according to the present invention; and

FIG. 3 is a drawing which shows an embodiment of a coating apparatus suitable to the method of manufacturing organic EL element according to the present invention.

### DETAILED DESCRIPTION OF THE PREFERRED EMBODIMENTS

<Relationship Between Contact Angle and Hole Transporting Layer>

While a conventional ink jet method requires execution of solvent removing processing and heat processing for long time after coating for patterning as described above, the inventor of the present invention considers that this is attributable to the following factor. That is, a coating composition containing a hole transportation material injected from an ink jet head takes the form of drops. Further, a widely used conventional coating composition has a relatively large contact angle with respect to a base material such as an ITO (indium tin oxide) layer. Hence, the coating composition supplied to the surface of the base material builds up as drops on the base material and coats the surface for patterning. To remove a solvent component and the like contained in the coating composition applied on the surface of the base material in this state and form a hole transporting layer, relatively long time is necessary. The inventor of the present invention has found from the consideration above and the results of various experiments that the contact angle of a coating composition with respect to a surface of a base material is closely related to the state of drying of the coating composition after coating for patterning.

A. The Coating Composition Described in Patent Literature 1 (Hereinafter Referred to as the “Conventional Coating Composition”)

The conventional coating composition uses a mixture (BAYTRON P) of PEDT (polyethylene dioxythiophene), which is a polythiophene derivative, and PSS (polystyrene sulfonic acid) as a hole transportation material. The conventional coating composition uses water, methanol, isopropyl alcohol, 1,3-dimethyl-2-imidazolidinone (DMI) as polar solvents, and uses γ-glycydil oxypropyl trimethoxy silane as a silane coupling agent. The contents of the respective ingredients are as shown in Table 1.

TABLE 1

| COATING | | CONTENT |
|---|---|---|
| COMPOSITION | NAME OF MATERIAL | (wt %) |
| HOLE | PEDT/PSS (BAYTRON P) | 7.25 |
| TRANSPORTION | | |
| MATERIAL | | |
| POLAR SOLVENT | WATER | 52.75 |
| | METHANOL | 5 |
| | ISOPROPYL ALCOHOL | 5 |
| | 1,3-DIMETHYL-2- | 30 |
| | IMIDAZOLIDINONE | |
| SILANE | γ-GLYCYDIL OXYPROPYL | 0.08 |
| COUPLING | TRIMETHOXY SILANE | |
| AGENT | | |

The contact angle with respect to a glass substrate was measured using a contact angle meter and found to be about 70 degrees.

When this coating composition is to be used for coating of an ITO layer (anode) for patterning by an ink jet method, as described in Patent Literature 1, solvent removing processing for twenty minutes and baking for ten minutes is necessary to form a hole transporting layer, taking up thirty minutes in total. The inventor of the present invention therefore studied use of a different coating method than an ink jet method. The other method was a method using the coating apparatus which the inventor has proposed in Japanese Patent Application No. 2002-207123, that is, a method requiring pouring of a coating composition upon a surface of an ITO layer enclosed by barrier walls. The structure and operations of this coating apparatus will be described later in detail.

The conventional coating composition was poured upon a surface of an ITO layer which was enclosed by barrier walls to coat the surface, the conventional coating composition did not spread uniformly over the exposed surfaces of the ITO layer as a whole, leaving the ITO layer partially exposed. In other words, using the conventional coating composition, it is not possible to favorably apply a hole transporting layer upon an ITO layer which corresponds to the “base material” or the “electrode” of the present invention, and form a hole transporting layer by drying thus applied hole transporting layer in a short period of time.

B. The Coating Composition According to the Embodiment

While changing the ingredients of coating compositions and the contents of the ingredients, the inventor of the present invention applied the coating composition upon glass substrates and measured various types of properties of the coating compositions. One of these coating compositions is the conventional coating composition shown in Table 1. The reason of using glass substrates was to test as many times as possible at a low cost, noting relatively expensive prices of ITO layers.

From the experiments, it was found that adjustment of the ingredients of a coating composition and the contents of the ingredients changed the contact angle of the coating composition with respect to a glass substrate. It was also found that a reduced contact angle made the contact composition spread uniformly over a surface of the glass substrate and that the solvents were removed from the coating composition in a short period of time after coating. The coating composition thus adjusted is the one shown in Table 2, for instance.

TABLE 2

| COATING | | CONTENT |
|---|---|---|
| COMPOSITION | NAME OF MATERIAL | (wt %) |
| HOLE | PEDT/PSS (BAYTRON P) | 0.95-1.05 |
| TRANSPORTION | | |
| MATERIAL | | |
| POLAR SOLVENT | WATER | 93.95-94.05 |
| | ETHANOL | 5 |

This coating composition is the coating composition according to the embodiment (hereinafter referred to as the “composition of the embodiment”). As shown in Table 2, a mixture (BAYTRON P) of PEDT (polyethylene dioxythiophene) and PSS (polystyrene sulfonic acid) is used as a hole transportation material, and water and ethanol are used as polar solvents. Various types of property values of the composition of the embodiment were measured, resulting in the result shown in Table 3.

TABLE 3

| | |
|---|---|
| VISCOSITY (mPa · s) | ≦10 |
| CONTACT ANGLE TO GLASS | ≦10 |
| SUBSTRATE (degrees) | |
| BOILING POINT (° C.) | 100-150 |
| CONTENT OF POLYMER (wt %) | 1 |
| pH | 1-2 |
| Na ION CONCENTRATION (ppm) | approximately 3 |
| SULPHATE ION CONCENTRATION | approximately 2 |
| (ppm) | |

Of the property values shown in Table 3, “VISCOSITY” was measured with a viscometer, while “CONTACT ANGLE TO GLASS SUBSTRATE” was measured with a contact angle meter and found out to be 10 degrees or less. The composition of the embodiment was applied upon an ITO layer for organic EL element using a coating apparatus which will be described later, and found to have a contact angle of about 35 degrees with respect to a surface of the ITO layer (corresponding to the “base material” of the present invention). The time needed to remove the solvents from thus applied composition of the embodiment after coating for pattern was about fifteen seconds at a room temperature, which is remarkably shorter than the time needed for removal of solvents from the conventional coating composition. In short, it is possible to tremendously reduce the time needed to form a hole transporting layer.

It was confirmed that with the surface of the ITO layer irradiated with ultraviolet light before coating for patterning with the composition of the embodiment and accordingly made hydrophilic, the contact angle of the composition of the embodiment with respect to the surface of the ITO layer further decreased even down to twenty degrees.

As described above, use of the coating composition according to the present invention makes it possible to uniformly apply the coating composition on an ITO layer and form a hole transporting layer in a short period of time after coating. Consequently, when a hole transporting layer is formed using this coating composition, the hole transporting layer can be formed favorably and efficiently. So a method of manufacturing organic EL element using the composition of the embodiment will be described in the following.

<Method of Manufacturing Organic EL Element>

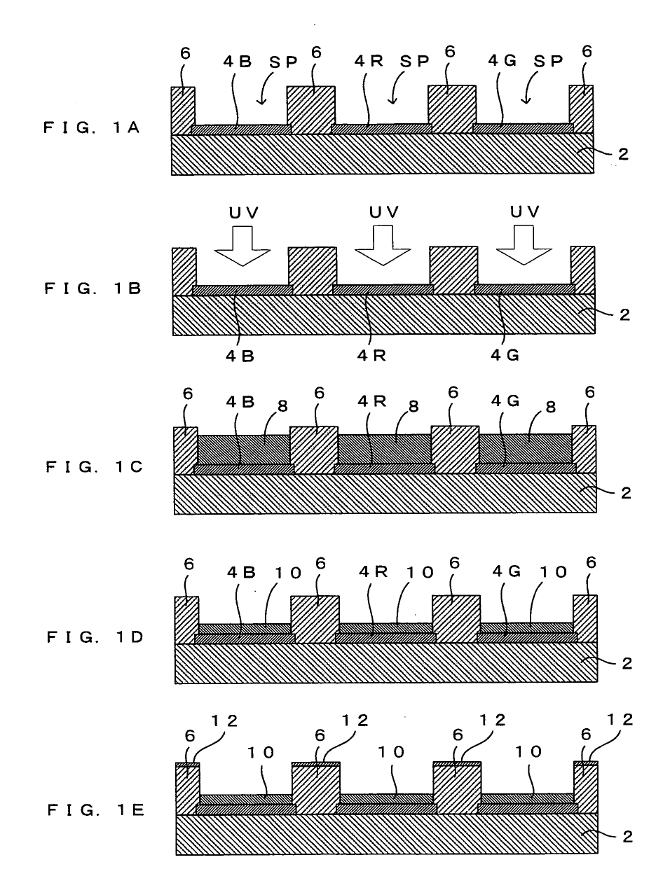

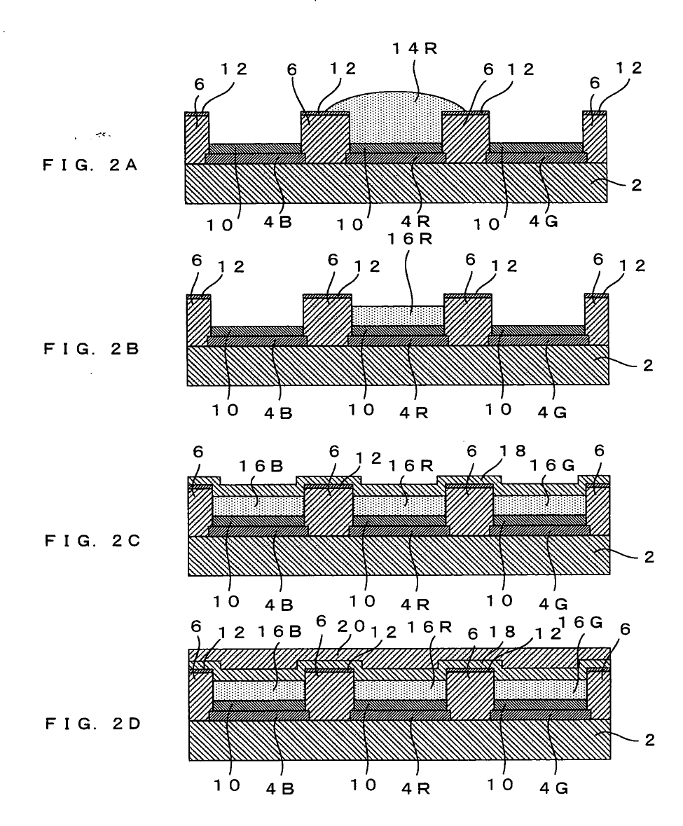

FIGS. 1A through 1E and 2A through 2D are drawings which show an embodiment of a method of manufacturing organic EL element according to the present invention. In this embodiment, first, after forming an ITO film on a substrate 2 which may be a glass substrate, a transparent plastic substrate or the like, plural first electrodes are patterned whose shapes are like stripes by means of a photolithographic technique (electrode forming step) as shown in FIG. 1A. The first electrodes correspond to the anode. FIGS. 1A through 1E and 2A through 2D show three types of the first electrodes 4R, 4G and 4B for red, green and blue. The first electrodes are preferably transparent electrodes. The ITO film may be replaced with a tin oxide film, a composite oxide film containing indium oxide and zinc oxide, etc.

Next, electrically insulated barrier walls (banks) 6 are formed by a photolithographic technique for instance, filling up the areas between the first electrodes (anode) 4R, 4G and 4B (barrier wall forming step). This provides prevention of color blending of organic EL materials formed in the manner described later, light leakage from between pixels, etc. The material of the barrier walls 6 is not particularly limited but may be any material which is resistant against a hole transportation material and an organic EL material. For instance, an acrylic resin, an epoxy resin, an organic material such as polyimide, an inorganic material such as liquid glass, or the like may be used.

Before forming a hole transporting layer, as shown in FIG. 1B, surfaces of the first electrodes (ITO) 4R, 4G and 4B are irradiated with ultraviolet light (hydrophilic processing). Irradiated with ultraviolet light, the surfaces of the first electrodes (ITO) 4R, 4G and 4B become hydrophilic.

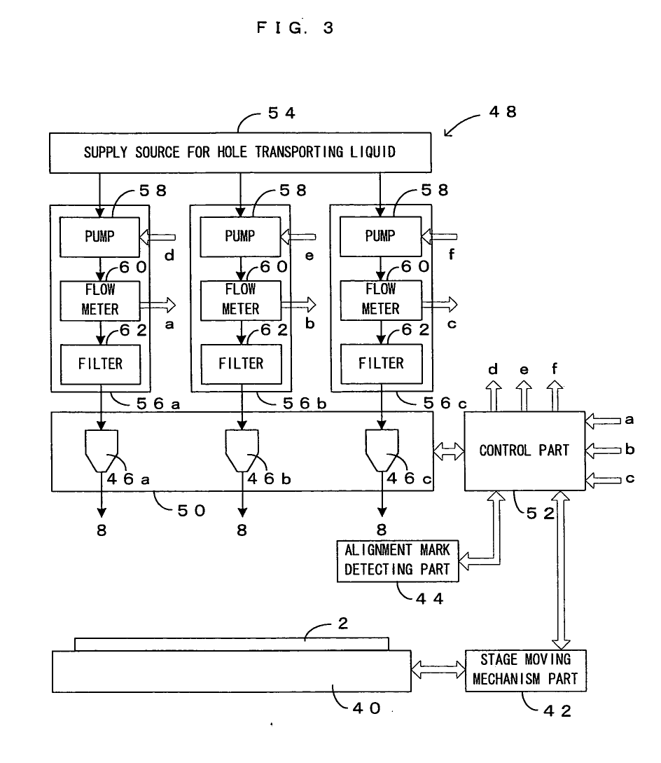

Following this, a hole transporting liquid 8 which is the same as the composition of the embodiment is selectively supplied between the barrier walls, i.e., in element spaces SP, thereby forming a hole transporting layer 10 on the first electrodes (4R, 4G, 4B) in the element spaces SP. To be more specific, the hole transporting liquid 8 which is the same as the composition of the embodiment shown in Table 2 is prepared in advance, and selectively supplied in the element spaces SP by a nozzle scan method (FIG. 1C). After this coating step, without heating the substrate 2, the hole transporting liquid 8 is dried naturally at a room temperature for about fifteen seconds for instance to remove the solvents out from the hole transporting liquid 8, and post-baked at 100° C. for five through ten minutes, whereby the hole transporting layer 10 is formed (FIG. 1D). As an apparatus for selectively supplying the hole transporting liquid 8 to the element spaces SP, a coating apparatus shown in FIG. 3 for example may be used.

The crests of the barrier walls 6 are then treated by plasma processing which uses CF₄ gas (fluorocarbon gas) and fluoridated (made liquid repellent). In consequence, fluorine-contained layers (layers of a material containing fluorine) 12 are formed on the crests of the barrier walls 6 (liquid repellent processing) as shown in FIG. 1E. The liquid repellent processing is not limited to fluoridation described above but may be any processing which makes the organic EL materials described later liquid repellent. For example, impregnation may be used which application of a polymer or a solvent swells up the material of the barrier walls 6. To be more specific, the crests of the barrier walls 6 are coated and impregnated with a fluorine-contained resin selected from among polytetrafluoroethylene (PTFE), a tetrafluoroethylene-hexafluoropropylene copolymer (FEP), tetrafluoroethylene-ethylene copolymer (ETFE) and polyvinylidene fluoride (PVDF), to thereby make the crests of the barrier walls 6 liquid repellent. Alternatively, the crests of the barrier walls 6 may be coated and impregnated with alcohol, such as toluene, xylene and benzene, which is insoluble to water which is a major ingredient of the hole transporting liquid 8, to thereby make the crests of the barrier walls 6 liquid repellent.

Next, between the barrier walls corresponding to the first electrodes 4R, an organic EL material 14R for the red color is supplied by a nozzle scan method and an organic EL layer 16R is formed on the first electrodes 4R via the hole transporting layer 10. To be more specific, as shown in FIG. 2A, the organic EL material 14R is supplied between the barrier walls until the red organic EL material 14R has flown onto the barrier walls corresponding to the first electrodes 4R and humps have been formed on the crests of the barrier walls 6. At this stage, since the fluorine-contained layers 12 have been formed on the crests of the barrier walls 6 and the crests of the barrier walls 6 have been made liquid repellent, the organic EL material 14R will not overflow beyond the barrier walls 6 and into between the neighboring barrier walls, and stop on the crests of the barrier walls 6 and stay as humps. As an apparatus for supplying the organic EL material 14R, the coating apparatus described in Japanese Patent Application Laid-Open Gazette No. 2002-75640 for instance may be used.

After completion of supplying of the organic EL material 14R, the substrate 2 is heated using a baking apparatus or the like, the organic EL material 14R is dried, and the organic EL layer 16R is formed (FIG. 2B).

Next, an organic EL layer 16G for the green color is formed on the first electrodes 4G via the hole transporting layer 10, and an organic EL layer 16B for the blue color is further formed on the first electrodes 4B via the hole transporting layer 10. The steps for forming these are identical to that for the red color and therefore will not be described. The organic EL layers may be formed one at a time for each color, or the organic EL materials 14R, 14G and 14B for the three colors may be supplied at the same time and dried.

As the organic EL layers 16R, 16G and 16B have been thus formed for the three colors as described above, a plurality of stripe-like second electrodes 18 are formed side by side on the substrate 2 by vacuum deposition such that the second electrodes 18 will be perpendicular to and faced against the first electrodes 4R, 4G and 4B, as shown in FIG. 2C. With this structure thus formed, the “organic EL element” of the present invention is obtained. In other words, the organic EL layers 16R, 16G and 16B are sandwiched between the first electrodes 4R, 4G and 4B which function as the anode and the second electrodes 18 which function as the cathode. This completes an organic EL display apparatus which is capable of displaying in full colors and in which the first electrodes 4R, 4G and 4B and the second electrodes 18 are arranged in a simple XY matrix. In this embodiment, a sealing layer 20 of a sealing material, such as an epoxy resin, an acrylic resin and liquid glass, is stacked on the substrate 2 for prevention of deterioration, damage and the like of the respective organic EL elements.

As described above, in this embodiment, since the hole transporting liquid 8 which is the composition of the embodiment is poured upon the first electrodes (ITO) 4R, 4G and 4B and the first electrodes are coated with the hole transporting liquid 8, the exposed surfaces as a whole of the first electrodes 4R, 4G and 4B enclosed by the barrier walls 6 is coated uniformly with the hole transporting liquid 8, and the hole transporting layer 10 is obtained favorably. Further, since the time needed to remove the solvents from thus applied hole transporting liquid 8 is substantially reduced, the hole transporting layer 10 is formed efficiently and the tact time is reduced remarkably. Meanwhile, this embodiment lowers the temperature for post baking down to 100° C. which is 200° C. according to the conventional methods.

<Coating Apparatus>

One embodiment of a coating apparatus for selectively supplying the hole transporting liquid 8 to the element spaces SP will now be described with reference to FIG. 3. FIG. 3 is a drawing which shows an embodiment of a coating apparatus which is suitable to the method of manufacturing organic EL element according to the present invention. This coating apparatus, as shown in FIG. 3, is comprised of a stage 40 which seats the substrate 2 on which organic EL elements are to be formed in the manner described above, a stage moving mechanism part 42 which moves this stage 40 in a predetermined direction (the lateral direction in FIG. 3), an alignment mark detecting part 44 which detects the locations of alignment marks formed on the substrate 2, a supply unit 48 which supplies the hole transporting liquid 8 to three nozzles 46a through 46c, a nozzle moving mechanism part 50 which moves the three nozzles 46a through 46c in a predetermined direction (the vertical direction in FIG. 3), and a control part 52 which controls the respective portions of the apparatus.

Of these components, as shown in FIG. 3, the supply unit 48 comprises a supply source 54 which stores the hole transporting liquid 8, and the supply source 54 is connected to three supply portions 56a through 56c through piping. These three supply portions 56a through 56c have the identical structures, and these supply portions 56a through 56c compress and feed the hole transporting liquid 8 stored in the supply source 54 respectively to the nozzles 46a through 46c so that the hole transporting liquid 8 will be injected out toward the substrate 2. To be more specific, the supply portions 56a through 56c each comprise a pump 58 for ejecting the hole transporting liquid 8 from the supply source 54, a flow meter 60 which detects the flow rate of the hole transporting liquid 8, and a filter 62 for removing foreign matters contained in the hole transporting liquid 8. In this embodiment, the hole transporting liquid 8 is thus injected toward the substrate 2 at each one of the nozzles 46a through 46c.

The nozzle moving mechanism part 50 maintains the three nozzles 46a through 46c side by side with holding members (not shown), and the coating pitches of the nozzles 46a through 46c can be varied. It is thus possible to change the coating pitches in accordance with how the barrier walls are disposed on the substrate 2.

As the alignment mark detecting part 44, a CCD camera may be used for example. In short, upon receipt of an instruction from the control part 52, the alignment mark detecting part 44 captures the images of alignment marks (not shown) formed on the four corners of the substrate 2 and outputs image data of thus shot alignment marks to the control part 52. On the other hand, the control part 52 calculates the locations of the alignment marks based on the image data shot by the alignment mark detecting part 44. Further, since the control part 52 has been fed in advance with layout data regarding the first electrodes 4R, 4G and 4B, the barrier walls 6 and the like designed using CAD (Computer Aided Design), the control part 52 calculates the start points for coating, namely, the coating start positions at which coating with the hole transporting liquid 8 is to start, based on the calculation result on the locations of the alignment marks and the layout data fed in advance regarding the barrier walls 6.

Besides the calculations above, the control part 52 controls the stage moving mechanism part 42 so as to move the stage 40 in a predetermined direction (the lateral direction in FIG. 3) by a predetermined amount, and controls the nozzle moving mechanism part 50 so as to move the nozzles 46a through 46c in a direction perpendicular to the stage 40 (the direction perpendicular to the plane of FIG. 3) by a predetermined amount, whereby the nozzles 46a through 46c move two-dimensionally relative to the substrate 2. Meanwhile, as the nozzles 46a through 46c move relative to the substrate 2, the control part 52 outputs commands d through f to the respective pumps 58 in accordance with detection values a through c received from the respective flow meters 60 so that a predetermined amount of the hole transporting liquid 8 will be pushed out from the nozzles 46a through 46c.

In the coating apparatus having this structure, when the substrate 2 as it is before coated with the hole transporting liquid 8 is mounted on the stage 40, the control part 52 feeds operation commands to the respective portions of the apparatus based on detection values from the respective portions of the apparatus, and pours the hole transporting liquid 8 between barrier walls (i.e., into the element spaces SP) in the following manner.

First, in response to a mark capture command from the control part 52, the alignment mark detecting part 44 captures the alignment marks on the four corners of the substrate 2 mounted on the stage 40 and outputs this image data to the control part 52. The control part 52, receiving this, calculates the locations of the alignment marks based on the image data and further calculates the start points for coating. In response to move commands from the control part 52, the stage moving mechanism part 42 and the nozzle moving mechanism part 50 operate, whereby the nozzles 46a through 46c are positioned at the start points. The three nozzles 46a through 46c are each positioned to each one of the three spaces between the barrier walls (the element spaces SP).

As the state ready to start coating is obtained, the control part 52 instructs the respective pumps 58 to start pouring the hole transporting liquid 8 between the barrier walls (i.e., into the element spaces SP) on the substrate 2 from the nozzles 46a through 46c, while moving the nozzles 46a through 46c in the direction perpendicular to the plane of FIG. 3 so that the hole transporting liquid 8 will move along and flow into the spaces between the barrier walls on the substrate 2. As a result, the hole transporting liquid 8 is poured into the three element spaces SP simultaneously. When the nozzles 46a through 46c have arrived at the ends of the element spaces SP, the respective pumps 58 are fed with stop commands, thereby stopping the pouring of the hole transporting liquid 8 into the element spaces SP on the substrate 2 from the nozzles 46a through 46c, and the nozzle moving mechanism part 50 is fed with a stop command, thereby stopping the movement of the nozzles. The control part 52 controls the coating amount of the hole transporting liquid 8 in accordance with the speeds at which the nozzles 46a through 46c move so that the hole transporting liquid 8 will be applied uniformly at the respective points in the element spaces SP which are shaped like stripes. Coating of the three rows of the element spaces SP with the hole transporting liquid 8 thus completes. The hole transporting liquid 8, owing to its own viscosity, spreads over the element spaces SP and levels off after poured on the hole transporting layer 14 in the element spaces SP, and the hole transporting liquid 8 of uniform thickness is obtained. The thickness of the hole transporting liquid 8 poured into the element spaces SP is adjustable depending upon the amount in which the hole transporting liquid 8 is poured.

Next, the stage 40 is fed three pitches, i.e., over the three rows of the element spaces SP, in preparation for coating of the next three rows of the element spaces SP with the hole transporting liquid 8. As for the first three rows of the element spaces SP, the hole transporting liquid 8 is poured into each one of the first three rows of the element spaces SP described earlier while moving the nozzles 46a through 46c along the spaces between the barrier walls with one ends of the element spaces SP used as the coating start positions and the other ends used as the coating stop positions. But as for the next three rows of the element spaces SP, the hole transporting liquid 8 is poured into each one of the next three rows of the element spaces SP while moving the nozzles 46a through 46c from the other ends of the element spaces SP to one ends in the opposite direction to the direction of the movement above.

As this operation is repeated, the hole transporting liquid 8 is poured into the spaces between the barrier walls (i.e., into the element spaces SP). Further, since the hole transporting liquid 8 is poured into the spaces between the barrier walls (i.e., into the element spaces SP) from the nozzles 46a through 46c for coating, it is possible to prevent the hole transporting liquid 8 from splashing during coating of the substrate 2 with the hole transporting liquid 8. This also makes it easy to control coating with the hole transporting liquid 8. Hence, it is possible to pour the hole transporting liquid 8 selectively into the spaces between the barrier walls (i.e., into the element spaces SP) without allowing the hole transporting liquid 8 adhere to the crests of the barrier walls 6. The coating apparatus shown in FIG. 3 is thus useful to implement the method of manufacturing organic EL element described earlier.

<Others>

The present invention is not limited to the preferred embodiments above, but may be modified in various manners in addition to the preferred embodiments above to the extent not deviating from the spirit of the invention. For instance, although the method of manufacturing organic EL element according to the embodiment described above requires that the surfaces of the first electrodes 4R, 4G and 4B are irradiated with ultraviolet light and made the surfaces hydrophilic, solvent cleaning processing may be exercised as the hydrophilic processing. Alternatively, the hydrophilic processing may be plasma processing utilizing corona discharge or atmospheric plasma. When a hole transporting layer is to be formed on a non-metallic base material such as a glass substrate, corona processing may be executed as the hydrophilic processing. Further, the hydrophilic processing is not indispensable but may be executed when needed.

In addition, although the method of manufacturing organic EL element according to the embodiment described above requires that the crests of the barrier walls 6 are treated by the liquid repellent processing after coating with the hole transporting liquid 8, the order of coating with the hole transporting liquid 8 and the liquid repellent processing may be reversed.

Further, although a hole transporting layer is formed on the first electrodes (ITO) 4R, 4G and 4B of the organic EL elements in the embodiments described above, applications of the present invention are not limited to this. The present invention is applicable generally to a coating composition used to uniformly form a hole transporting layer on a predetermined base material and a method of forming a hole transporting layer using such a coating composition.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

1. A coating composition which is to be applied on a surface of a predetermined base material and which contains a hole transportation material, wherein the contact angle of said coating composition with respect to the surface of said base material is 35 degrees or smaller.

2. The coating composition of claim 1, wherein said base material is a transparent electrode of indium tin oxide.

3. The coating composition of claim 1, wherein the contact angle with respect to a surface of a glass substrate is 10 degrees or smaller.

4. A method of manufacturing organic EL element, comprising:
an electrode forming step of forming an electrode having a predetermined pattern on a substrate;
a barrier wall forming step of forming barrier walls on said substrate such that said barrier walls will correspond to said pattern; and
a coating step of coating exposed surfaces of said electrode which are enclosed by said barrier walls by means of pouring a coating composition thereon, and
wherein said coating composition contains a hole transportation material and has a contact angle of 35 degrees or smaller with respect to the surfaces of said electrode.

5. The method of manufacturing organic EL element of claim 4, further comprising a hydrophilic processing step of treating said exposed surfaces of said electrode by hydrophilic processing before said coating step.

6. The method of manufacturing organic EL element of claim 5, wherein said hydrophilic processing step is solvent cleaning processing of cleaning said exposed surfaces of said electrode with a solvent, ultraviolet light irradiation processing of irradiating said exposed surfaces of said electrode with ultraviolet light, or plasma processing of said exposed surfaces of said electrode.
